(19) United States
(12) Patent Application Publication
(10) Pub. No.: US 2025/0133848 A1
(43) Pub. Date: Apr. 24, 2025

(54) LIGHT-RECEIVING DEVICE AND ELECTRONIC APPARATUS

(71) Applicant: SONY SEMICONDUCTOR SOLUTIONS CORPORATION, Kanagawa (JP)

(72) Inventors: Tooru IDEKOBA, Kumamoto (JP); Shinichiro NOUDO, Kanagawa (JP); Takashi KOJIMA, Kanagawa (JP); Yuma ONO, Kanagawa (JP); Yoshiyuki OHBA, Kumamoto (JP)

(73) Assignee: SONY SEMICONDUCTOR SOLUTIONS CORPORATION, Kanagawa (JP)

(21) Appl. No.: 18/691,999

(22) PCT Filed: Mar. 24, 2022
(86) PCT No.: PCT/JP2022/014049

§ 371 Date: Mar. 14, 2024

(30) Foreign Application Priority Data
Sep. 27, 2021 (JP) 2021-157295

(51) Int. Cl. H10F 39/00

(52) U.S. Cl. CPC H10F 39/805; H10F 39/8063

(57) ABSTRACT

A light-receiving device according to an embodiment of the present disclosure includes: a metal oxide film having a maximum value of an extinction coefficient of not less than 0.1 in a wavelength range from 200 nm to 380 nm; and a light receiving unit that receives ultraviolet light that passes through the metal oxide film.

### TECHNICAL FIELD

The present disclosure relates to a light-receiving device and an electronic apparatus.

### BACKGROUND ART

There is proposed a photoelectric conversion device that includes an anti-reflection film including a silicon oxide film and also including a silicon nitride film having an extinction coefficient k of not more than 0.01 in a wavelength region of 200 nm to 380 nm (Patent Literature 1).

### CITATION LIST

### Patent Literature

Patent Literature 1: Japanese Unexamined Patent Application Publication No. 2017-92054

### SUMMARY OF THE INVENTION

For an element that receives light in an ultraviolet region, there is a demand to improve the performance.

It is desirable to provide a light-receiving device having favorable performance.

A light-receiving device according to an embodiment of the present disclosure includes: a metal oxide film having a maximum value of an extinction coefficient of not less than 0.1 in a wavelength range from 200 nm to 380 nm; and a light receiving unit that receives ultraviolet light that passes through the metal oxide film.

An electronic apparatus according to an embodiment of the present disclosure includes a light-receiving device including a metal oxide film and a light receiving unit that receives ultraviolet light that passes through the metal oxide film. The metal oxide film has a maximum value of an extinction coefficient of not less than 0.1 in a wavelength range from 200 nm to 380 nm.

### BRIEF DESCRIPTION OF THE DRAWINGS

FIG. 1 is a block diagram illustrating one example of the entire configuration of an imaging unit according to a first embodiment of the present disclosure.

FIG. 2 is a diagram illustrating one example of a pixel section of the imaging unit according to the first embodiment of the present disclosure.

FIG. 3 is a diagram illustrating one example of a cross-sectional configuration of the imaging unit according to the first embodiment of the present disclosure.

FIG. 4 is a diagram illustrating one example of results of experiments on ultraviolet-ray irradiation.

FIG. 5 is a diagram illustrating one example of extinction coefficient of a metal oxide film according to the first embodiment of the present disclosure.

FIG. 6 is a diagram illustrating one example of relationships between transmittance and film thickness of the metal oxide film according to the first embodiment of the present disclosure.

FIG. 7 is a diagram illustrating one example of a method of manufacturing the imaging unit according to the first embodiment of the present disclosure.

FIG. 8 is a diagram illustrating one example of a method of manufacturing the imaging unit according to the first embodiment of the present disclosure.

FIG. 9 is a diagram illustrating one example of a method of manufacturing the imaging unit according to the first embodiment of the present disclosure.

FIG. 10 is a diagram illustrating one example of a method of manufacturing the imaging unit according to the first embodiment of the present disclosure.

FIG. 11 is a diagram illustrating one example of a method of manufacturing the imaging unit according to the first embodiment of the present disclosure.

FIG. 12 is a block diagram illustrating one example of the entire configuration of an imaging unit according to a second embodiment of the present disclosure.

FIG. 13 is a diagram illustrating an example of a configuration of a pixel of the imaging unit according to the second embodiment of the present disclosure.

FIG. 14 is a diagram illustrating one example of a cross-sectional configuration of the imaging unit according to the second embodiment of the present disclosure.

FIG. 15 is a block diagram illustrating an example of a configuration of an electronic apparatus including the imaging unit.

### MODES FOR CARRYING OUT THE INVENTION

Below, embodiments of the present disclosure will be described in detail with reference to the drawings. Note that description will be made in the following order.
1. First Embodiment
2. Second Embodiment
3. Modification Example
   3-1. First Modification Example
   3-2. Second Modification Example
4. Application Example

### 1. First Embodiment

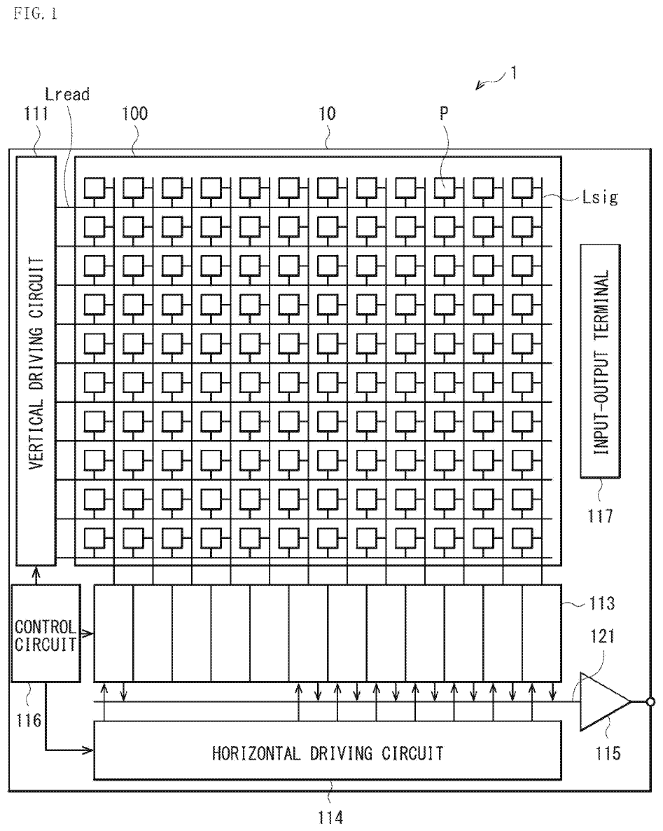

FIG. 1 is a block diagram illustrating one example of the entire configuration of an imaging unit serving as one example of a light-receiving device according to a first embodiment of the present disclosure. An imaging unit 1 serving as a light-receiving device is an element that receives ultraviolet light, and has sensitivity to ultraviolet light. The imaging unit (light-receiving device) 1 can be applied as an ultraviolet ray sensor (UV sensor) that detects ultraviolet ray. The imaging unit 1 is, for example, a CMOS (complementary metal oxide semiconductor) imaging sensor. The imaging unit 1 can be used in an electronic apparatus such as a digital still camera or a video camera.

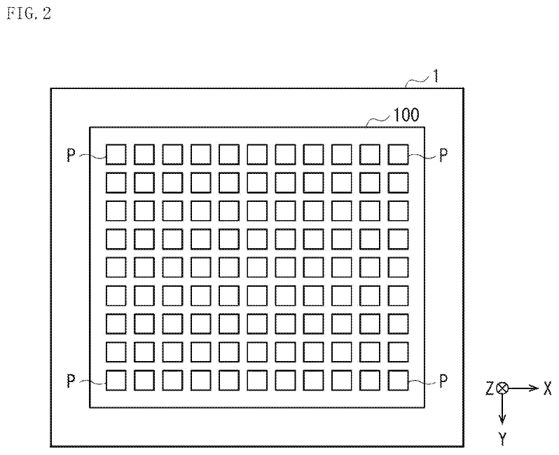

In the imaging unit 1, a pixel P including a light receiving unit (photoelectric converter) is arrayed in a matrix manner. The imaging unit 1 includes, as an imaging area, a pixel section 100 in which a plurality of pixels P is arrayed two-dimensionally in a matrix manner, as illustrated in FIG. 2. Note that, as illustrated in FIG. 2, it is assume that a direction in which light from a subject enters is a Z axis direction, a left-right direction on a paper plane and perpendicular to the Z axis direction is an X axis direction, and an up-down direction on a paper plane and perpendicular to the Z axis and the X axis is a Y axis direction. In the following drawings, directions may be given by using the arrowed directions in FIG. 2 as references.

### [Schematic Configuration of Imaging Unit]

The imaging unit 1 receives incident light (imaging light) from a subject through an optical lens system (not illustrated). The imaging unit 1 converts, on a pixel basis, the amount of incident light formed as an image on an imaging plane, into an electrical signal, and outputs the electrical signal as a pixel signal. In a region around the pixel section 100, the imaging unit 1 includes, for example, a vertical driving circuit 111, a column signal-processing circuit 113, a horizontal driving circuit 114, an output circuit 115, a control circuit 116, an input-output terminal 117, and the like.

In the pixel section 100, the plurality of pixels P is arrayed two-dimensionally in a matrix manner. The pixel section 100 includes a plurality of pixel rows each including a plurality of pixels P and arranged in a horizontal direction (transverse direction on a paper plane), and also includes a plurality of pixel columns each including a plurality of pixels P and arranged in a vertical direction (vertical direction on a paper plane). The pixel section 100 may include an effective pixel region and a black-reference pixel region. The effective pixel region is used to read out a signal based on a signal charge generated through reception of light from a subject and photoelectric conversion. The black-reference pixel region is used to output optical black serving as a reference of a black level. The black-reference pixel region is provided, for example, at an outer peripheral portion of the effective pixel region.

For example, in the pixel section 100, a pixel drive line Lread (a row selection line and a reset control line) is wired for each of the pixel rows, and a vertical signal line Lsig is wired for each of the pixel columns. The pixel drive line Lread is a line used to transmit a drive signal for reading out a signal from pixels. One end of the pixel drive line Lread is coupled to an output terminal corresponding to each of the pixel rows of the vertical driving circuit 111.

The vertical driving circuit 111 includes a shift register, an address decoder, and the like. The vertical driving circuit 111 is a pixel drive section that drives each of the pixels P of the pixel section 100 on a row basis, for example. The column signal-processing circuit 113 includes an amplifier, a horizontal selection switch, and the like provided for each of the vertical signal lines Lsig. A signal outputted from each of the pixels P of a pixel row selected and scanned by the vertical driving circuit 111 is supplied to the column signal-processing circuit 113 through the vertical signal line Lsig.

The horizontal driving circuit 114 includes a shift register, an address decoder, and the like, and sequentially drives individual horizontal selection switches of the column signal-processing circuit 113 while scanning them. Through this selection and scanning by the horizontal driving circuit 114, signals from individual pixels transmitted through each vertical signal line Lsig are sequentially outputted to a horizontal signal line 121, and are transmitted through this horizontal signal line 121 to the outside of the substrate (semiconductor substrate) 10.

The output circuit 115 is configured to apply signal processing to signals sequentially supplied from each of the column signal-processing circuits 113 through the horizontal signal line 121 to output it. For example, the output circuit 115 may only perform buffering or may perform black-level adjustment, correction of variation between columns, various types of digital signal processing, and the like. Note that it may be possible to employ a configuration in which signal processing such as eliminating noises or amplifying signals is performed in the column signal-processing circuit 113 on the basis of signals from the black-reference pixel region.

Circuit sections including the vertical driving circuit 111, the column signal-processing circuit 113, the horizontal driving circuit 114, the horizontal signal line 121, and the output circuit 115 may be formed at the substrate 10, or may be disposed at an external controlling IC. In addition these circuit sections may be formed at another substrate coupled through a cable or the like.

The control circuit 116 receives a clock provided from the outside of the substrate 10 or data for giving an instruction as to an operating mode, or the like, and outputs data such as internal information on the imaging unit 1. The control circuit 116 includes a timing generator that generates various types of timing signals, and performs driving control of peripheral circuits such as the vertical driving circuit 111, the column signal-processing circuit 113, and the horizontal driving circuit 114 on the basis of the various types of timing signals generated by the timing generator.

The control circuit 116 generates a clock signal or a control signal or the like, for example, on the basis of a vertical synchronization signal, a horizontal synchronization signal, and a master clock. The clock signal and the control signal serve as a reference for operations of the vertical driving circuit 111, the column signal-processing circuit 113, the horizontal driving circuit 114, and the like. The clock signal, the control signal, and the like generated by the control circuit 116 are inputted into the vertical driving circuit 111, the column signal-processing circuit 113, the horizontal driving circuit 114, and the like. The input-output terminal 117 is configured to communicate signals with the outside.

### [Configuration of Pixel]

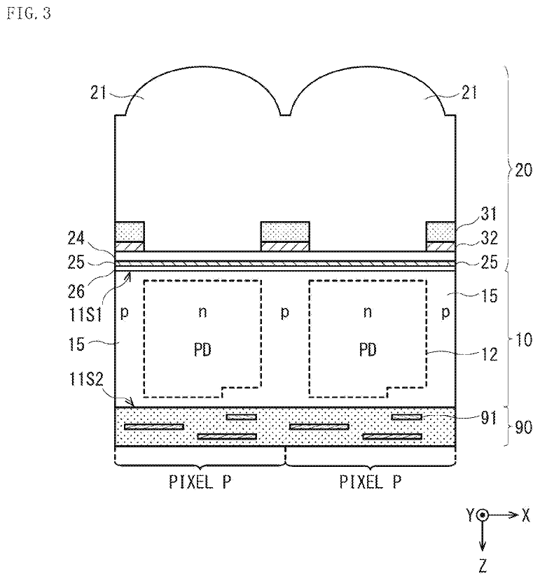

FIG. 3 is a diagram illustrating one example of a cross-sectional configuration of the imaging unit according to the first embodiment. For example, the imaging unit 1 has a configuration in which the substrate 10, a light guiding section 20, a multi-layer wiring-line layer 90 are stacked in the Z axis direction. The substrate 10 includes a semiconductor substrate 10 including a first surface 11S1 and a second surface 11S2 that are opposed to each other. The light guiding section 20 is provided at the first surface 11S1 side of the semiconductor substrate 10. The multi-layer wiring-line layer 90 is provided at the second surface 11S2 side of the semiconductor substrate 10. In other words, the light guiding section 20 is provided at the side where light enters from the optical lens system. In addition, the multi-layer wiring-line layer 90 is provided at a side that is oppose to the side where light enters. The imaging unit 1 is a so-called back-illuminated type imaging unit.

The semiconductor substrate 10 includes, for example, a silicon substrate. The light receiving unit of the pixel P is a photoelectric converter 12 including, for example, a photodiode (PD), and includes a pn junction at a predetermined region of the semiconductor substrate 10. In the example illustrated in FIG. 3, the photoelectric converter 12 is formed so as to extend in the entire region of the thickness direction of the semiconductor substrate 10, and includes a pn junction-type photodiode including an n-type semiconductor region and a p-type semiconductor region that faces both the front and rear surfaces of the semiconductor substrate 10. Note that the p-type semiconductor region that faces both the front and rear surfaces of the semiconductor substrate 10 also serves as a positive-hole charge accumulation region used to reduce a dark current. Note that the substrate 10 does not necessarily include a silicon substrate, and may include other semiconductor materials.

The photoelectric converter 12 according to the present embodiment is configured to have sensitivity to a wavelength range of ultraviolet light including a wavelength range from 200 nm to 380 nm. The photoelectric converter 12 performs photoelectric conversion to the entering ultraviolet light, thereby being able to generate a charge. In the semiconductor substrate 10, a plurality of photoelectric converters 12 is provided along the first surface 11S1 and the second surface 11S2.

For example, the multi-layer wiring-line layer 90 has a configuration in which a plurality of wiring line layers is stacked with an interlayer insulating layer being interposed between them. Circuits (a transfer transistor, a reset transistor, an amplification transistor, or the like) used to read out a pixel signal based on the charge generated by the photoelectric converter 12 are formed in the semiconductor substrate 10 and the multi-layer wiring-line layer 90. In addition, for example, the vertical driving circuit 111, the column signal-processing circuit 113, the horizontal driving circuit 114, the output circuit 115, the control circuit 116, the input-output terminal 117, and the like that have been described above are formed in the semiconductor substrate 10 and the multi-layer wiring-line layer 90.

The pixel P includes a transfer transistor, a reset transistor, a selection transistor, an amplification transistor (amplifier transistor), and the like that serve as pixel transistors. Note that the pixel P may not include the selection transistor. Individual pixels each including the photoelectric converter 12 and the pixel transistors are separated by a separation section 15 including the p-type semiconductor region. The separation section 15 is provided at a boundary between adjacent pixels P, and separates the pixels P. The separation section 15 is provided between adjacent photoelectric converters 12, and in other words, is an element separation region. Note that, in FIG. 3, one pixel transistor is used as a representative of a plurality of pixel transistors, and is schematically illustrated as a gate electrode 91.

A plurality of wiring line layers of the multi-layer wiring-line layer 90 is formed, for example, using aluminum (Al), copper (Cu), tungsten (W), or the like. In addition, the wiring line layers may be formed using polysilicon (Poly-Si). For example, the interlayer insulating layer is formed as a single layer film including one type of silicon oxide (SiOₓ), silicon nitride (SiNₓ), silicon oxynitride (SiOₓN_{y}), and the like, or is formed as a stacked film including two or more types of these elements.

The light guiding section 20 includes a lens section 21 that condenses light, an insulation film 24, a metal oxide film 25, and a fixed charge film 26, and guides, toward the semiconductor substrate 10 side, light entering from the upper side in FIG. 3. The light guiding section 20 is stacked at the semiconductor substrate 10 in a thickness direction perpendicular to the first surface 11S1 of the semiconductor substrate 10.

The lens section 21 is an optical member also called an on-chip lens, and is provided at the insulation film 24. Light from a subject enters the lens section 21, for example, through the optical lens system such as an imaging lens. The lens section 21 includes a material that allows ultraviolet light to pass through, and guides the entering light toward the photoelectric converter 12. The height of the lens section 21 in the Z axis direction, that is, the thickness of the lens section 21 in the Z axis direction is set such that light entering the lens section 21 is condensed to the photoelectric converter 12.

In the present embodiment, the lens section 21 includes silicon oxide. This enables the lens section 21 to gather the entering ultraviolet light to the photoelectric converter 12 while allowing the light to pass through. The lens section 21 may be formed using P-TEOS. In this case, it is possible to increase the throughput in forming a film. Note that the lens section 21 may be configured using a material containing silicon oxide or may be configured using another material.

The insulation film 24 is an insulating layer provided between the lens section 21 and the photoelectric converter 12. The insulation film 24 is configured using an oxide film including, for example, silicon oxide or the like. The insulation film 24 may be formed using P-TEOS. Note that the insulation film 24 may be configured using a material containing silicon oxide or may be configured using another material.

The fixed charge film 26 is provided between the insulation film 24 and the photoelectric converter 12. The fixed charge film 26 is provided, for example, at an oxide film (not illustrated) formed at the first surface 11S1 of the semiconductor substrate 10. The fixed charge film 26 is formed so as to cover the first surface 11S1 of the semiconductor substrate 10.

In the example illustrated in FIG. 3, the fixed charge film 26 is provided at the first surface 11S1 of the semiconductor substrate 10 so as to cover a portion where the photoelectric converter 12 is formed and a portion where the separation section 15 is formed. The fixed charge film 26 is formed along the first surface 11S1 of the semiconductor substrate 10 so as to have a predetermined thickness.

The fixed charge film 26 is, for example, a film having a negative fixed charge, and is formed using a high dielectric body. As the fixed charge film 26 is formed so as to have a negative fixed charge, an electric field is applied to an interface with the photoelectric converter 12 due to the negative fixed charge. With this electric field, a positive charge (hole) accumulation region is formed, which makes it possible to suppress occurrence of a dark current at an interface with the semiconductor substrate 10. The fixed charge film 26 is formed so as to include, for example, one or more oxides with elements of hafnium (Hf), zirconium (Zr), aluminum (Al), tantalum (Ta), titanium (Ti), magnesium (Mg), yttrium (Y), lanthanoid (La), and the like.

The fixed charge film 26 is configured using aluminum oxide (Al₂O₃) as one example. An aluminum oxide (Al₂O₃) film causes strong pinning and has a low extinction coefficient in an ultraviolet ray region, and hence, is preferable for an ultraviolet ray sensor. Note that it may be possible to provide a film having a positive fixed charge as the fixed charge film 26.

The imaging unit 1 may include a light shielding section 31 above the insulation film 24 as in the example illustrated in FIG. 3. The light shielding section 31 is configured using a member that blocks light, and is provided at an interface between adjacent pixels P. The light shielding section 31 is configured, for example, using a metal material that blocks light, specifically, using tungsten or aluminum or the like. In the example illustrated in FIG. 3, the light shielding section 31 is a light blocking film provided around the photoelectric converter 12, and prevent light from leaking to surrounding pixels.

By forming the light shielding section 31 at a portion corresponding to a boundary between pixels on the insulation film 24, it is possible to suppress crosstalk between pixels. Note that it is only necessary that the light shielding section 31 includes a material that blocks light. However, it is preferable that the light shielding section 31 includes a material having a high light shielding property and making it possible to highly accurately perform machining through micromachining such as etching. Note that a member 32 used to improve an adhesive property between the light shielding section 31 and the insulation film 24 may be provided between the light shielding section 31 and the insulation film 24. This member 32 may be configured, for example, using a barrier metal such as titanium. The member 32 may also be called a close-contact layer. Furthermore, although illustration is not given, it may be possible to form a trench used to separate pixels P, and the inside of the trench may be filled with an oxide film or a metal film.

The metal oxide film 25 is a metal oxide film including tantalum oxide (Ta₂O₅) or the like, and is provided at the fixed charge film 26. For example, the metal oxide film 25 is provided between the lens section 21 and the photoelectric converter 12 so as to be stacked at the fixed charge film 26. The photoelectric converter 12 receives light that has passed through the lens section 21 and the metal oxide film 25. The photoelectric converter 12 receives ultraviolet light that enters through the lens section 21 and the metal oxide film 25, and generates a charge corresponding to the amount of the received light.

In addition, in the example illustrated in FIG. 3, the metal oxide film 25 is formed at substantially the entire surface of the fixed charge film 26. Note that the metal oxide film 25 does not necessarily need to be provided at substantially the entire surface of the fixed charge film 26. For example, the metal oxide film 25 may be provided only at the upper side of a section where the photoelectric converter 12 is formed. The metal oxide film 25 and the fixed charge film 26 may also serve as an anti-reflection film that reduces reflection.

The metal oxide film 25 may be configured as a single film, or may be configured such that a plurality of films is stacked. For example, the metal oxide film 25 includes a tantalum oxide (Ta₂O₅) film, a niobium oxide (Nb₂O₅) film, a tungsten oxide (WO₃) film, or a film obtaining by stacking these films.

In the present embodiment, the metal oxide film 25 is formed such that the maximum value of an extinction coefficient is not less than 0.1 in a wavelength range from 200 nm to 380 nm. This makes it possible to suppress a deterioration in characteristics resulting from irradiation with ultraviolet ray while securing a quantum efficiency (QE) concerning light having a wavelength range of ultraviolet light. Below, description will be further made of the imaging unit 1 according to the present embodiment by making a comparison with a comparative example.

The comparative example is a case in which the imaging unit 1 in FIG. 3 does not include the metal oxide film 25. The present inventors confirm that it is possible to improve sensitivity (UV sensitivity) to ultraviolet light in a case of the imaging unit 1 that does not include the metal oxide film 25. However, as a result of experiments on ultraviolet-ray irradiation for a long period of time, they found that, in a case of the comparative example, an increase in a dark current and a reduction in UV sensitivity (hereinafter, referred to as a UV irradiation damage) are large.

In addition, the present inventors examined a relationship between the extinction coefficient of the metal oxide film 25 and the degree of the UV irradiation damage (the amount of increase in the dark current and the amount of reduction in the UV sensitivity). As a result, they found that, by providing the metal oxide film 25 having the maximum value of the extinction coefficient of not less than 0.1 in a wavelength range from 200 nm to 380 nm, it is possible to suppress the UV irradiation damage. It is considered that the reason that it is possible to suppress the UV irradiation damage is that occurrence of the interface state can be reduced by using such a metal oxide film 25 to reduce the irradiation of the Si interface of the semiconductor substrate 10 with ultraviolet ray.

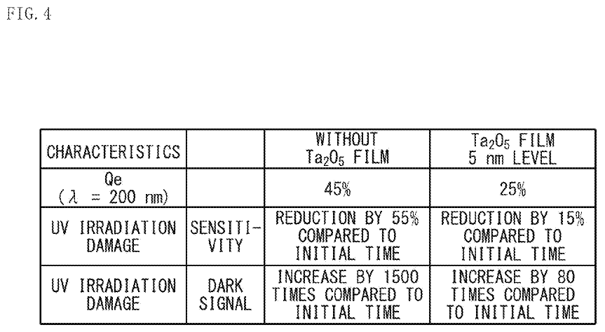

FIG. 4 is a diagram illustrating one example of a result of experiments on ultraviolet-ray irradiation. The wavelength of the irradiated ultraviolet ray is 193 nm, and the radiant intensity is 1.0 mW/cm². In addition, the duration of irradiation with ultraviolet ray is one hour, and the total amount of irradiation energy is 3.6 J/cm². FIG. 4 shows the quantum efficiency and the amount of UV irradiation damage in a case where no tantalum oxide (Ta₂O₅) film is provided and in a case where a tantalum oxide (Ta₂O₅) film having a thickness of 5 nm level is provided.

In a case where no tantalum oxide film is provided, the initial quantum efficiency Qe is high whereas the amount of reduction in the quantum efficiency due to UV irradiation is 55% and is large. In addition, the dark signal corresponding to the amount of dark current increases by 1500 times. On the other hand, in a case where a tantalum oxide film is provided, the initial quantum efficiency Qe decreases whereas the amount of reduction in the quantum efficiency due to UV irradiation is 15% and reduces. In addition, the dark signal increases by 80 times, and is suppressed. In this manner, in a case where the metal oxide film 25 is provided, it can be understood that, although the initial quantum efficiency Qe reduces, the effect of suppressing the UV irradiation damage is high.

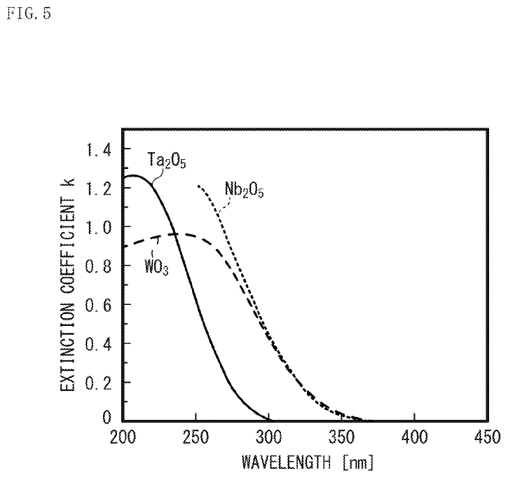

FIG. 5 is a diagram illustrating one example of the extinction coefficient of the metal oxide film 25 according to the first embodiment. In FIG. 5, the horizontal axis indicates the wavelength, and the vertical axis indicates the extinction coefficient k. The extinction coefficient is measured using, for example, a spectroscopic ellipsometer. The extinction coefficient at a wavelength of not more than 250 nm can be measured in an environment where nitrogen is purged, by taking absorption of atmospheric air into consideration.

In FIG. 5, the solid line indicates the extinction coefficient of a tantalum oxide film (Ta₂O₅ film). The tantalum oxide film has the maximum value of a tantalum oxide film of not less than 0.1 in a wavelength range from 200 nm to 380 nm. In addition, in FIG. 5, the dotted line indicates the extinction coefficient of a niobium oxide film (Nb₂O₅ film), and the dashed line indicates the extinction coefficient of a tungsten oxide film (WO₃ film). The niobium oxide film and the tungsten oxide film also each have the maximum value of an extinction coefficient of not less than 0.1 in a wavelength range from 200 nm to 380 nm. It can be understood that such a metal oxide film 25 absorbs a certain amount of light having an ultraviolet-light region.

The imaging unit 1 including the metal oxide film 25 makes it possible to reduce the UV irradiation damage, as compared with a case where the imaging unit 1 does not include the metal oxide film 25. It is possible to suppress an increase in the interface state resulting from irradiation with ultraviolet light, and suppress an increase in the dark current. In addition, it is possible to suppress a reduction in sensitivity of the pixel P relative to the entering ultraviolet light, and suppress a deterioration in the quantum efficiency of the pixel P.

Note that it may be possible to provide a metal oxide film 25 having the minimum value of an extinction coefficient of not less than 0.4 in a wavelength range from 200 nm to 250 nm, and also having an average value of an extinction coefficient of not less than 0.09 in a wavelength range from 250 nm to 380 nm. By forming, as the metal oxide film 25, a tantalum oxide film, a tungsten oxide film, and the like that satisfy this condition, it is possible to effectively suppress the UV irradiation damage.

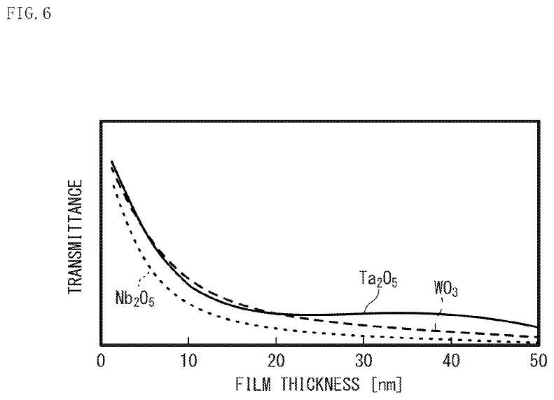

FIG. 6 is a diagram illustrating one example of a relationship between the transmittance and the film thickness of the metal oxide film 25 according to the first embodiment. In FIG. 6, the horizontal axis indicates the film thickness, and the vertical axis schematically indicates the transmittance relative to the ultraviolet light. In FIG. 6, the solid line indicates the transmittance of the tantalum oxide film (Ta₂O₅ film). In addition, the dotted line indicates the transmittance of the niobium oxide film (Nb₂O₅ film), and the dashed line indicates the transmittance of the tungsten oxide film (WO₃ film). As illustrated in FIG. 6, when the film thickness of the metal oxide film 25 is larger than 20 nm, the transmittance reduces, the amount of light passing through reduces, and the quantum efficiency largely deteriorates.

Thus, in the present embodiment, the metal oxide film 25 is formed so as to have a film thickness of not less than 1 nm and not more than 20 nm. With this configuration, it is possible to suppress a reduction in the amount of light received by the photoelectric converter 12, and secure the quantum efficiency necessary for the imaging unit 1. Note that the film thickness of the metal oxide film 25 may be set to be not less than 1 nm and not more than 10 nm. With this configuration, it is possible to effectively suppress a deterioration in the quantum efficiency.

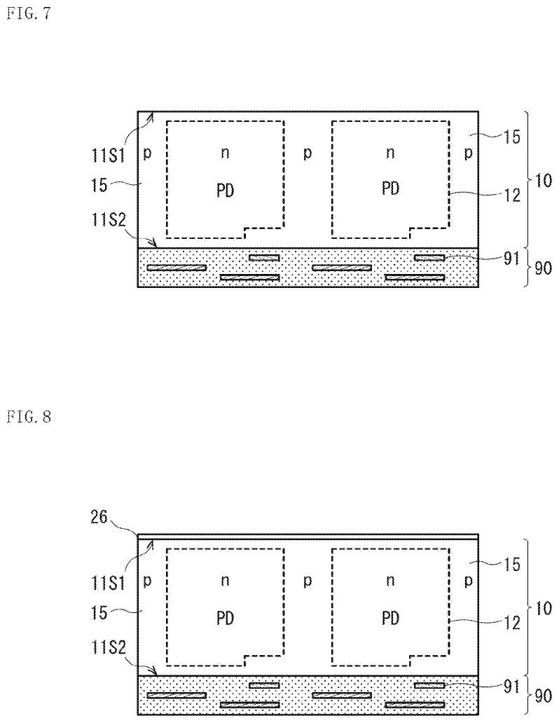

FIGS. 7 to 11 are diagrams each illustrating one example of a method of manufacturing an imaging unit according to the first embodiment. First, as illustrated in FIG. 7, a photodiode PD corresponding to each pixel P separated at the separation section 15 including a p-type semiconductor region is formed in a region where a pixel region of the semiconductor substrate 10 including silicon is supposed to be formed. Note that the photodiode PD is formed so as to extend in the entire region of the thickness direction of the semiconductor substrate 10, and includes a pn junction-type photodiode including an n-type semiconductor region and a p-type semiconductor region that faces both the front and rear surfaces of the semiconductor substrate 10.

A p-type semiconductor well region that is in contact with the separation section 15 is formed in a region corresponding to each pixel P at a front surface of the semiconductor substrate 10 that is at the opposite side to the light entrance surface. A pixel transistor of each pixel P is formed within this p-type semiconductor well region. Note that the pixel transistor is formed so as to include a source region, a drain region, a gate insulation film, and a gate electrode. In addition, the multi-layer wiring-line layer 90 is formed at an upper portion of the front surface of the semiconductor substrate 10 that is at the opposite side to the light entrance surface. In the multi-layer wiring-line layer 90, a plurality of layers of wiring lines are disposed with an interlayer insulation film being interposed between them. Note that a chemical oxide film is formed at the rear surface of the substrate through chemical solution processing.

Next, as illustrated in FIG. 8, the fixed charge film 26 is formed at the front surface of the semiconductor substrate 10 at the light entrance surface side. For example, an ALD (Atomic Layer Deposition) method is used under a condition of a film formation temperature that falls in a range of 200 to 300° C. to form, for example, a film of aluminum oxide (Al₂O₃ film) having a film thickness that falls in a range of 1 to 20 nm, thereby forming the fixed charge film 26.

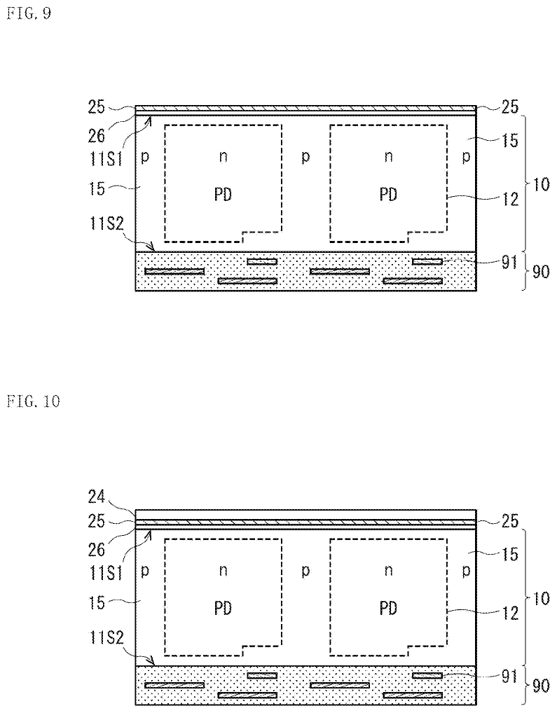

In addition, the metal oxide film 25 is formed at the fixed charge film 26, as illustrated in FIG. 9. As this metal oxide film 25, it may be possible to deposit tantalum oxide (Ta₂O₅) through reactive sputtering using a mixture gas of oxygen gas and argon gas, for example. In this case, a film of tantalum oxide is formed at a film formation temperature ranging from a room temperature to 400° C. such that no damage is left in the wiring line layer. The tantalum oxide is set to have a film thickness that falls in a range of approximately 1 nm to 20 nm by taking the transmittance of ultraviolet ray into consideration. More desirably, it is preferable that the film thickness of the tantalum oxide should fall in a range of approximately 1 nm to 10 nm.

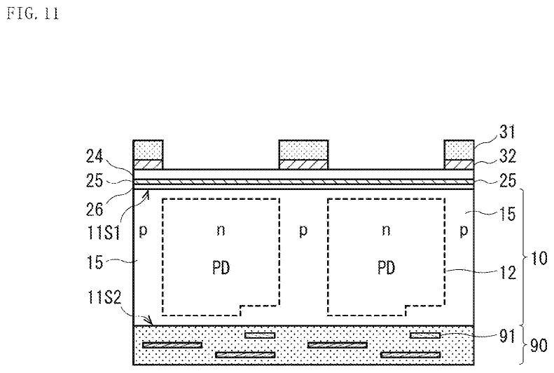

Next, an oxide film is formed as the insulation film 24 at the metal oxide film 25, as illustrated in FIG. 10. The insulation film 24 is formed, for example, through a plasma CVD (chemical vapor deposition) method at a film formation temperature of not more than 400° C. such that no damage is left in the wiring line layer. Note that, for example, a film of silicon oxide (SiO₂) is formed as the insulation film 24 so as to have a film thickness that falls in a range of 50 nm to 200 nm such that no blister is generated.

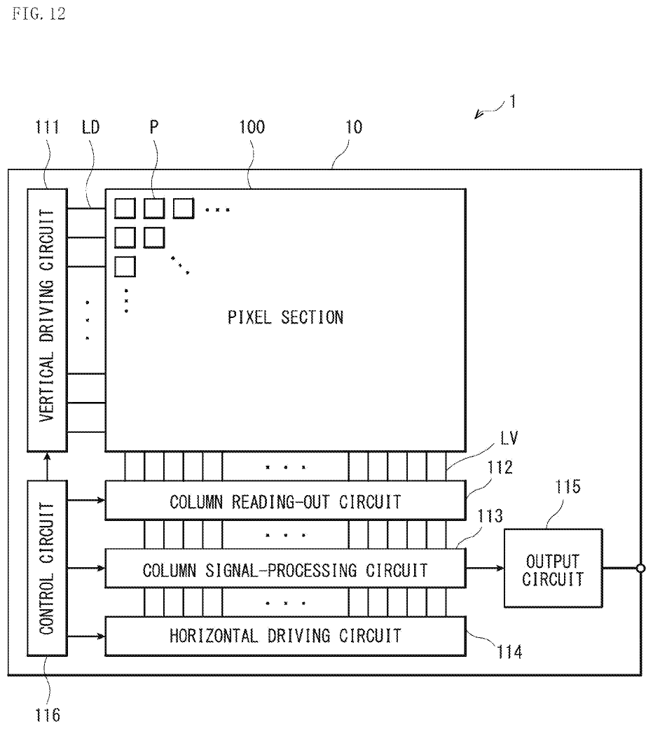

Furthermore, the light shielding section 31 is formed at the insulation film 24, as illustrated in FIG. 11. For the light shielding section 31, for example, a metal film, more specifically, a tungsten (W) or the like is formed at the upper surface of the insulation film 24, for example, through sputtering. The light shielding section 31 may have a film thickness that falls in a range of 100 to 400 nm so as to be able to block ultraviolet ray or a stray light component other than ultraviolet light. In a case where the adhesive property is poor, it may be possible to form, for example, a film of titanium or the like of 1 to 50 nm as the member 32 including a barrier metal. Note that, in a case where there is no concern for crosstalk in the effective pixel region where light is sensed, no light shielding section 31 may be provided. However, it is desirable to provide the light shielding section 31 at a pixel in the black-reference pixel region.

Next, patterning processing is performed to form an opening portion used to introduce ultraviolet light at a region corresponding to the photodiode PD. The patterning processing here may be performed such that the light shielding section 31 is selectively etched and removed through a resist mask (not illustrated) to form the light shielding section 31 at a boundary between individual pixels. Note that wet etching or dry etching may be used for the etching, and by using dry etching, it is possible to highly precisely obtain the micro-line width of the light shielding section 31.

After this, the lens section 21 is formed at the light entrance surface side of the semiconductor substrate 10. For example, for the material of the lens section 21, a film including silicon oxide, more specifically, a film including silicon oxide and formed through a plasma chemical vapor deposition (Plasma-Enhanced Chemical Vapor Deposition; PECVD) method using a gas containing a tetraethoxysilane (TEOS) gas is formed at a film formation temperature of not more than 400° C. A silicon oxide film formed through the PECVD method using a gas containing a TEOS gas is called a P-TEOS film.

Next, a resist is applied. After exposure and development, a resist shape is obtained through reflow in a thermal treatment, and dry etching is performed. In this manner, a curved shape is transferred on the silicon oxide, whereby a lens function can be achieved. Through the manufacturing method as described above, it is possible to manufacture the imaging unit 1 illustrated in FIG. 3. Note that the method of manufacturing an imaging unit described above is merely one example, and it may be possible to use other manufacturing methods.

### [Workings and Effects]

The light-receiving device (imaging unit) 1 according to the present embodiment includes: the metal oxide film 25 having the maximum value of an extinction coefficient of not less than 0.1 in a wavelength range from 200 nm to 380 nm; and the light receiving unit (photoelectric converter 12) that receives ultraviolet light that passes through the metal oxide film 25.

Since the imaging unit 1 according to the present embodiment includes the metal oxide film 25 having the maximum value of an extinction coefficient of not less than 0.1 in a wavelength range from 200 nm to 380 nm, it is possible to secure UV sensitivity and suppress the UV irradiation damage. This makes it possible to achieve the imaging unit 1 having high performance relative to ultraviolet light.

### 2. Second Embodiment

Next, a second embodiment of the present disclosure will be described. Below, the same reference characters are attached to configuration elements similar to those in the embodiment described above, and explanation thereof will not be repeated on an as-necessary basis.

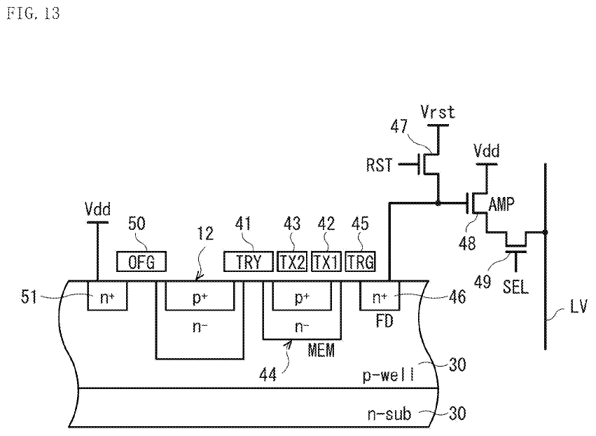

FIG. 12 is a block diagram illustrating one example of the entire configuration of an imaging unit serving as one example of a light-receiving device according to the second embodiment. The imaging unit 1 is, for example, a CMOS imaging sensor. As illustrated in FIG. 12, the imaging unit 1 includes the pixel section 100, the vertical driving circuit 111, a column reading-out circuit 112, the column signal-processing circuit 113, the horizontal driving circuit 114, the output circuit 115, and the control circuit 116. These pixel section 100, the vertical driving circuit 111, the column reading-out circuit 112, the column signal-processing circuit 113, the horizontal driving circuit 114, the output circuit 115, and the control circuit 116 are provided at the same semiconductor substrate or are provided at a plurality of stacked semiconductor substrates that are electrically coupled to each other.

In the pixel section 100, the plurality of pixels P is arrayed two-dimensionally in a matrix manner. In addition, the pixel section 100 may include a region in which a dummy pixel having a structure in which no photodiode is provided, a light shielding pixel at which the light receiving surface is shielded from light to block light coming from the outside, and the like are arrayed in rows and/or columns manner.

In the pixel section 100, pixels are arrayed in a matrix manner such that, for each row, a pixel drive line LD is formed along a left-right direction (direction in which pixels in a pixel row are arrayed) in the drawing, and for each column, a vertical pixel wiring line (vertical signal line) LV is formed along an up-down direction (direction in which pixels in a pixel column are arrayed) in the drawing. One end of the pixel drive line LD is coupled to an output terminal of the vertical driving circuit 111 that corresponds to each row.

The column reading-out circuit 112 at least includes: a circuit that supplies, for each column, a constant current to a pixel P in a selected row within the pixel section 100; a current mirror circuit; a switch that changes pixels P serving as the target of reading-out; and the like. The column reading-out circuit 112 together with a transistor of a selected pixel within the pixel section 100 constitutes an amplifier, and converts an optical charge signal into a voltage signal to output it to the vertical signal line LV.

The vertical driving circuit 111 includes a shift register, an address decoder, and the like, and drives individual pixels P of the pixel section 100 at the same time for all the pixels or on a row basis or the like. Although illustration is not given for the specific configuration thereof, this vertical driving circuit 111 includes a reading-out scanning system, and also includes a sweeping-out scanning system, or a collective sweeping-out and collective transferring system.

The reading-out scanning system sequentially selects and scans a pixel P of the pixel section 100 on a row basis, in order to read out a pixel signal from the pixel P. In a case of driving a row (rolling shutter operation), sweeping-out is performed such that, for a reading-out row to be read out and scanned by the reading-out scanning system, sweeping-out and scanning are performed ahead of this reading-out and scanning by a period of time of a shutter speed.

In addition, in a case of global exposure (global shutter operation), collective sweeping-out is performed ahead of collective transferring by a period of time of a shutter speed. With such sweeping-out, unnecessary charges are swept out (reset) from a photodiode of a pixel P of the reading-out row. Then, with the sweeping-out (reset) of unnecessary charges, a so-called electronic shutter operation is performed. Here, the electronic shutter operation represents an operation of discarding unnecessary optical charges accumulated in a photodiode just before it, and starting another exposure (starting accumulation of optical charges).

A signal read out through the reading-out operation by the reading-out scanning system corresponds to the amount of light entering on and after the reading-out operation immediately before it or entering on and after the electronic shutter operation. In a case of row driving, a period of time (exposure time) in which optical charges are accumulated in a pixel P is a period of time from timing of reading out through the reading-out operation immediately before it or timing of sweeping out through the electronic shutter operation to timing of reading out through a reading-out operation at this time. In a case of global exposure, the accumulation period of time (exposure time) is a period of time from the collective sweeping-out to the collective transferring.

A pixel signal outputted from each of the pixels P in a pixel row selected and scanned by the vertical driving circuit 111 is supplied to the column signal-processing circuit 113 through each vertical signal line LV. For each pixel column of the pixel section 100, the column signal-processing circuit 113 performs predetermined signal processing to the pixel signal outputted from each of the pixels P in the selected row through the vertical signal line LV, and temporarily holds pixel signals to which the signal processing has been performed.

Specifically, as for the signal processing, the column signal-processing circuit 113 at least performs noise removing processing such as CDS (Correlated Double Sampling) processing, for example. This CDS processing by the column signal-processing circuit 113 removes fixed pattern noises specific to a pixel, which include a reset noise or variation in threshold values of an amplification transistor AMP. Note that it may be possible to employ a configuration in which, in addition to the noise removing processing, the column signal-processing circuit 113 also has an AD conversion function, and outputs a pixel signal as a digital signal.

The horizontal driving circuit 114 includes a shift register, an address decoder, and the like, and sequentially selects a unit circuit of the column signal-processing circuit 113 that corresponds to a pixel column. Through this selection and scanning by the horizontal driving circuit 114, pixel signals to which the signal processing has been performed in the column signal-processing circuit 113 are sequentially outputted to the output circuit 115.

The control circuit 116 includes a timing generator that generates various types of timing signals or the like, and controls driving of the vertical driving circuit 111, the column signal-processing circuit 113, the horizontal driving circuit 114, and the like, on the basis of the various types of timing signals generated by the timing generator.

The imaging unit 1 further includes the output circuit 115 and a data storage unit (not illustrated). The output circuit 115 has at least an adding processing function, and performs various types of signal processing such as adding processing to a pixel signal outputted from the column signal-processing circuit 113. At the time when the output circuit 115 performs signal processing, the data storage unit temporarily holds data necessary for the processing. The output circuit 115 and the data storage unit may include a process performed by an external signal processing unit provided at a substrate differing from the imaging unit 1, for example, performed by a DSP (digital signal processor) or software, or may be mounted at the same substrate as the imaging unit.

### [Configuration of Pixel]

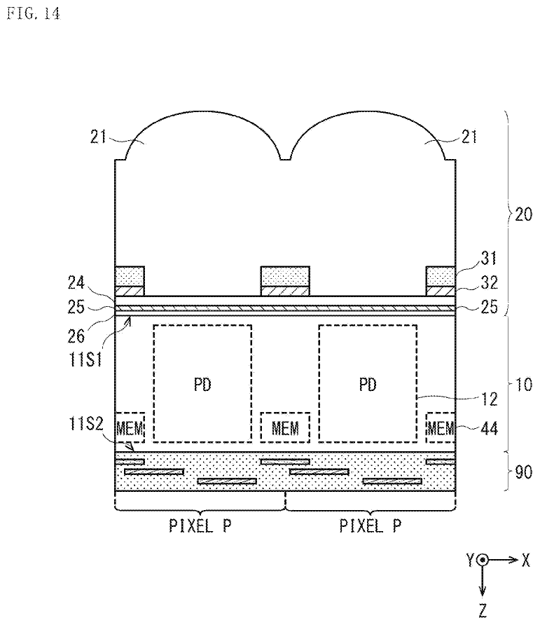

FIG. 13 is a diagram illustrating an example of the configuration of a pixel of the imaging unit according to the second embodiment. The pixel P includes a photodiode PD. The photodiode PD serves as one example of a light receiving unit (photoelectric converter 12). The photodiode PD is formed, for example, by forming a p-type layer on a substrate front surface side of a p-type well layer formed on an n-type substrate, and embedding an n-type embedded layer. That is, the photodiode is an embedded-type photodiode. Note that the n-type embedded layer has a concentration of impurities that achieves a depleted state at the time of discharging charges.

In addition to the photodiode PD, the pixel P includes a TRY gate 41, a TX1 gate 42, a TX2 gate 43, and a charge holder (MEM) 44. The TRY gate 41 is a transfer unit, and is coupled between the photodiode PD and the charge holder 44. Each of the TX1 gate 42 and the TX2 gate 43 is a transfer unit, and is disposed near the charge holder 44.

The charge holder 44 is formed, for example, by forming a p-type layer on a substrate front surface side of a p-type well layer formed on an n-type substrate, and embedding an n-type embedded layer. Note that the n-type embedded layer of the charge holder 44 may be formed using an n-type diffusion region. Specifically, it is only necessary to form n-type diffusion region inside of the p-type well layer, and form the p-type layer at the front surface side of the substrate. This makes it possible to prevent a dark current generated at the Si—SiO₂ interface from accumulating in an n-type diffusion region of the charge holder 44, which makes it possible to improve the quality of an image of the imaging unit 1.

Upon application of a drive signal TRY to a gate electrode, the TRY gate 41 transfers, to the charge holder 44, a charge photoelectrically converted at the photodiode PD and accumulated at the inside of the photodiode PD. In addition, the TRY gate 41 also functions as a gate that prevents a charge from reversely flowing from the charge holder 44 to the photodiode PD.

The TX1 gate 42 functions as a gate at the time of transferring a charge from the charge holder 44 to a floating diffusion region (FD: Floating Diffusion) that will be described later. In addition, the TX1 gate 42 also functions as a gate used to hold a charge at the charge holder 44. The TX2 gate 43 functions as a gate at the time of transferring a charge from the photodiode PD to the charge holder 44. Furthermore, the TX2 gate 43 also functions as a gate used to hold a charge at the charge holder 44.

In the charge holder 44, upon application of the drive signal TX2 and the drive signal TX1 to the gate electrode of the TX2 gate 43 and the gate electrode of the TX1 gate 42, respectively, modulation is applied to the charge holder 44. That is, as the drive signal TX2 and the drive signal TX1 are applied to the gate electrode of the TX2 gate 43 and the gate electrode of the TX1 gate 42, respectively, it is possible to deepen the potential of the charge holder 44. This makes it possible to increase the saturation charge amount of the charge holder 44, as compared with a case where modulation is not applied.

In addition, the pixel P further includes a TRG gate 45 and a floating diffusion region 46. The TRG gate 45 is a transfer unit, and upon application of the drive signal TRG to the gate electrode, a charge accumulated in the charge holder 44 is transferred to the floating diffusion region 46. The floating diffusion region 46 is a charge-voltage conversion unit including an n-type layer, and converts, into a voltage, a charge transferred from the charge holder 44 through the TRG gate.

The pixel P further includes a reset transistor (RST) 47, an amplification transistor (AMP) 48, and a selection transistor (SEL) 49. Note that the example illustrated in FIG. 13 gives an example in which an n-channel MOS transistor is used for the reset transistor 47, the amplification transistor 48, and the selection transistor 49. However, the configurations of the reset transistor 47, the amplification transistor 48, and the selection transistor 49 are not limited to the example illustrated in FIG. 13.

The reset transistor 47 is coupled between a power supply Vrst and the floating diffusion region 46. Upon application of the drive signal RST to the gate electrode, the reset transistor 47 resets the floating diffusion region 46. The amplification transistor 48 includes a drain electrode coupled to a power supply Vdd, also includes a gate electrode coupled to the floating diffusion region 46, and reads out a voltage of this floating diffusion region 46. The selection transistor 49 includes a drain electrode coupled to the source electrode of the amplification transistor 48 and also includes a source electrode coupled to the vertical signal line LV. Upon application of the drive signal SEL to the gate electrode, the selection transistor 49 selects a pixel P from which a pixel signal is to be read out.

Note that the example illustrated in FIG. 13 gives an example in which the selection transistor 49 is coupled between the source electrode of the amplification transistor 48 and the vertical signal line LV. However, the selection transistor 49 may be coupled between the power supply Vdd and the drain electrode of the amplification transistor 48. Note that one or a plurality items from among the reset transistor 47, the amplification transistor 48, and the selection transistor 49 may not be provided depending on a method of reading out a pixel signal.

In addition, the pixel P includes an overflow gate (OFG) 50 used to prevent blooming. Upon application of a drive signal OFG to the gate electrode at the time of starting exposure, this overflow gate 50 discharges a charge of the photodiode PD to the n-type layer 51 coupled to the power supply Vdd.

The imaging unit 1 including pixels P that has been described makes it possible to achieve a global shutter operation (global exposure) by starting exposure of all the pixels at the same time and ending the exposure of all the pixels at the same time. In addition, through this global shutter operation, it is possible to achieve imaging without distortion in an exposure period for all the pixels at the same time. Note that the example illustrated in FIG. 13 gives an example in which an n-type embedded channel is formed at the p-type well layer to configure a pixel P. However, it may be possible to use an opposite conductive type for each of the components. In this case, the relationships concerning potentials are all opposite.

### [Configuration of Pixel]

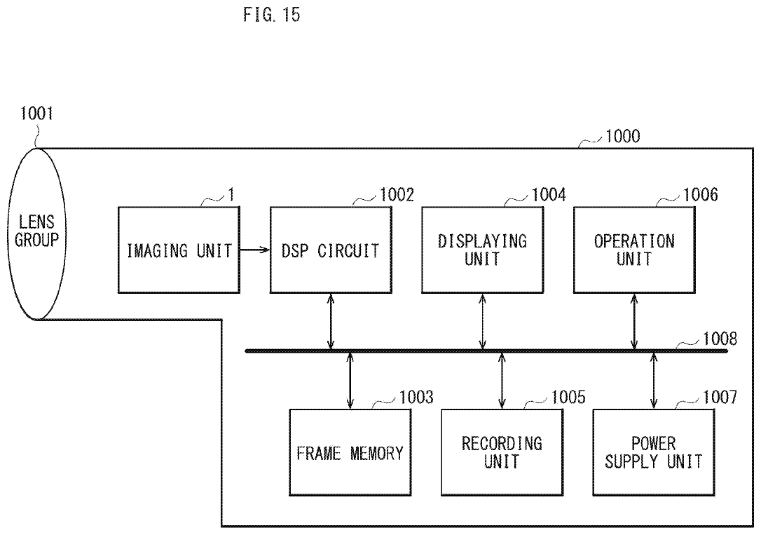

FIG. 14 is a diagram illustrating one example of a cross-sectional configuration of the imaging unit according to the second embodiment. In the semiconductor substrate 10, a charge holder (MEM) 44 is provided for each of the pixels P. The light shielding section 31 includes an opening portion only in a region corresponding to the photoelectric converter (photodiode) 12 so as to prevent light from entering regions other than the photoelectric converter (photodiode) 12, and allows light entering the photoelectric converter 12 to pass through.

Note that, in a case where ultraviolet ray is absorbed only at the front surface of the semiconductor substrate 10, the light shielding section 31 may not be provided because the charge holder 44 is disposed at the wiring line layer side of the semiconductor substrate 10 and is spaced apart from the light irradiation surface side. However, it is desirable that the light shielding section 31 should be provided at a pixel in the black-reference pixel region.

Basically, an ultraviolet ray sensor is often used in a Machine Vision inspection in industrial applications. In a Machine Vision inspection, it is strongly demanded to reduce its duration by inspecting specimens traveling at high speed. However, in a case of rolling shutter, there is a possibility that rolling shutter distortion or blurring happens relative to a mobile body.

In addition, in a case of global shutter, light from specimens at the moment can be received by all the pixels at the same time. Thus, there occurs no trouble described above, and it is possible to improve the inspection accuracy. That is, it is preferable to combine the imaging unit 1 according to the present embodiment with the global shutter function. In addition, it is possible to reduce cost by eliminating the crosstalk suppressing structure as described above.

Next, modification examples of the present disclosure will be described. Below, the same reference characters are attached to constituent elements similar to those in the embodiments described above, and explanation thereof will not be repeated on an as-necessary basis.

### 3. Modification Examples

### 3-1. First Modification Example

The metal oxide film 25 may include niobium oxide or tungsten oxide. In addition, the metal oxide film 25 may include a multi-layer film including two or more of tantalum oxide, niobium oxide, and tungsten oxide. Such a metal oxide film 25 includes a material that absorbs a certain amount of ultraviolet light, and it is possible to suppress the UV irradiation damage.

### 3-2. Second Modification Example

It is desirable that the metal oxide film 25 should include a material having the standard free energy of formation (see “Metals Data Book, fourth revised edition, edited by The Japan Institute of Metals and Materials, Maruzen Publishing Co., Ltd.”) equal to or higher than the standard free energy of formation of silicon oxide. The standard free energy of formation of each of tantalum oxide, niobium oxide, and tungsten oxide is equal to or higher than the standard free energy of formation of silicon oxide.

In a case where there is provided the metal oxide film 25 having the “standard free energy of formation of oxide” that is higher than silicon oxide that constitutes an oxide film at the semiconductor substrate 10, it is more energetically stable in terms of chemical reaction to take oxygen atoms away from the metal oxide film 25, than a case where oxygen atoms are taken away from the oxide film. Thus, it is possible to: suppress a phenomenon in which oxygen atoms are taken away from the oxide film due to irradiation with ultraviolet ray; protect an interface layer between the oxide film and the front surface of the semiconductor substrate 10 at the light entrance surface side; and suppress occurrence of a dark current due to formation of an interface state. The results of experiments performed by the present inventors show that it is desirable to use tantalum oxide, niobium oxide, and tungsten oxide from the viewpoint of characterization including defects of a solid-state imaging device, and in particular, the present inventors obtain a result indicating that tantalum oxide is preferable.

### 4. Application Example

The imaging unit 1 or the like described above can be applied, for example, to a camera system such as a digital still camera or a video camera, a mobile phone having an imaging function, or various types of electronic apparatuses having an imaging function. FIG. 15 is a diagram illustrating a schematic configuration of an electronic apparatus 1000.

The electronic apparatus 1000 includes, for example, a lens group 1001, the imaging unit 1, a DSP (digital signal processor) circuit 1002, a frame memory 1003, a displaying unit 1004, a recording unit 1005, an operation unit 1006, and a power supply unit 1007, and these are coupled to each other through a bus line 1008.

The lens group 1001 receives incident light (imaging light) from a subject, and forms an image on an imaging plane of the imaging unit 1. On a pixel basis, the imaging unit 1 converts, into an electrical signal, the amount of incident light formed as an image on the imaging plane by the lens group 1001, and supplies it to the DSP circuit 1002 as a pixel signal.

The DSP circuit 1002 is a signal processing circuit that processes a signal supplied from the imaging unit 1. The DSP circuit 1002 outputs image data obtained by processing the signal from the imaging unit 1. The frame memory 1003 temporarily holds, on a frame basis, image data processed by the DSP circuit 1002.

The displaying unit 1004 includes, for example, a panel-type display device such as a liquid crystal panel or an organic EL (Electro Luminescence) panel, and records image data on a moving image or a still image captured by the imaging unit 1, in a recording medium such as a semiconductor memory or a hard disk.

In response to an operation performed by a user, the operation unit 1006 outputs an operation signal concerning various types of functions that the electronic apparatus 1000 owns. The power supply unit 1007 supplies various types of power supply serving as a power supply for operating the DSP circuit 1002, the frame memory 1003, the displaying unit 1004, the recording unit 1005, and the operation unit 1006, to these supply targets on an as-necessary basis.

These are descriptions of the present disclosure by giving the embodiments and the modification examples. However, the present technology is not limited to the embodiments or the like described above, and various modifications are possible. For example, the modification examples described above have been described as modification examples of the embodiments described above. However, it may be possible to combine the configuration of the individual modification examples on an as-necessary basis. For example, the present disclosure is not limited to the back-illuminated type imaging sensor, and is able to be applied to a front-illuminated type imaging sensor.

It should be noted that the effects described in the present description are merely examples, and are not limited to those described. Other effects may be possible. In addition, the present disclosure can be take the following configurations.

(1)

A light-receiving device including:
a metal oxide film having a maximum value of an extinction coefficient of not less than 0.1 in a wavelength range from 200 nm to 380 nm; and
a light receiving unit that receives ultraviolet light that passes through the metal oxide film.
   (2)

The light-receiving device according to (1) described above, in which
the metal oxide film has a minimum value of the extinction coefficient of not less than 0.4 in a wavelength range from 200 nm to 250 nm, and
the metal oxide film has an average value of the extinction coefficient of not less than 0.09 in a wavelength range from 250 nm to 380 nm.
   (3)

The light-receiving device according to (1) or (2), in which
a wavelength range of the ultraviolet light includes the wavelength range from 200 nm to 380 nm; and
the light receiving unit photoelectrically converts the ultraviolet light that passes through the metal oxide film.
   (4)

The light-receiving device according to any one of (1) to (3) described above, in which the metal oxide film includes one or more of tantalum oxide, niobium oxide, and tungsten oxide.

(5)

The light-receiving device according to any one of (1) to (4) described above, in which the metal oxide film has a film thickness of not less than 1 nm and not more than 20 nm.

(6)

The light-receiving device according to any one of (1) to (5) described above, in which
the metal oxide film includes tantalum oxide, and
the metal oxide film has a film thickness of not less than 1 nm and not more than 20 nm.
   (7)

The light-receiving device according to any one of (1) to (6) described above, in which standard free energy of formation of the metal oxide film is equal to or more than standard free energy of formation of silicon oxide.

(8)

A light-receiving device including:

a lens that allows ultraviolet light to pass through;

a metal oxide film where light that passes through the lens enters; and

a light receiving unit that receives the light that passes through the lens and the metal oxide film, in which
the metal oxide film has a maximum value of an extinction coefficient of not less than 0.1 in a wavelength range from 200 nm to 380 nm.
   (9)

The light-receiving device according to (8) described above, in which the lens is configured using silicon oxide.

(10)

The light-receiving device according to (8) or (9) described above, in which
the metal oxide film has a minimum value of the extinction coefficient of not less than 0.4 in a wavelength range from 200 nm to 250 nm, and
the metal oxide film has an average value of the extinction coefficient of not less than 0.09 in a wavelength range from 250 nm to 380 nm.
   (11)

The light-receiving device according to any one of (8) to (10) described above, in which a wavelength range of the ultraviolet light includes the wavelength range from 200 nm to 380 nm.

(12)

The light-receiving device according to according to any one of (8) to (11) described above, in which the metal oxide film includes one or more of tantalum oxide, niobium oxide, and tungsten oxide.

(13)

The light-receiving device according to any one of (8) to (12) described above, in which the metal oxide film has a film thickness of not less than 1 nm and not more than 20 nm.

(14)

The light-receiving device according to any one of (8) to (13) described above, in which
the metal oxide film includes tantalum oxide, and
the metal oxide film has a film thickness of not less than 1 nm and not more than 20 nm.
   (15)

The light-receiving device according to any one of (8) to (14) described above, in which standard free energy of formation of the metal oxide film is equal to or more than standard free energy of formation of silicon oxide.

(16)

The light-receiving device according to any one of (1) to (15) described above, including: a fixed charge film provided between the metal oxide film and the light receiving unit.

(17)

The light-receiving device according to (16) described above, in which the fixed charge film includes aluminum oxide.

(18)

The light-receiving device according to any one of (1) to (17) described above, including:
a substrate including a plurality of the light receiving units, a plurality of holding sections, and a plurality of transfer units, the light receiving unit receiving light to generate a charge, the holding sections holding the charge, the transfer units transferring the charge generated by the light receiving units to the holding sections;
a wiring line layer provided on a side opposite to a side where the light enters; and
a controller that controls the plurality of the transfer units in a global shutter manner.
   (19)

An electronic apparatus including a light-receiving device including a metal oxide film and a light receiving unit that receives ultraviolet light that passes through the metal oxide film, in which

the metal oxide film has a maximum value of an extinction coefficient of not less than 0.1 in a wavelength range from 200 nm to 380 nm.

(20)

An electronic apparatus including a light-receiving device including:
a light-receiving device including:
   a lens that allows ultraviolet light to pass through;
   a metal oxide film where light that passes through the lens enters; and
   a light receiving unit that receives the light that passes through the lens and the metal oxide film, wherein
the metal oxide film has a maximum value of an extinction coefficient of not less than 0.1 in a wavelength range from 200 nm to 380 nm.

This application claims priority based on Japanese Patent Application No. 2021-157295 filed on Sep. 27, 2021 with Japan Patent Office, the entire contents of which are incorporated in this application by reference.

It should be understood by those skilled in the art that various modifications, combinations, sub-combinations and alterations can be made so as to correspond to design requirements and other factors, and they are within the scope of the appended claims or the equivalents thereof.

What is claimed is:

1. A light-receiving device, comprising:
a metal oxide film having a maximum value of an extinction coefficient of not less than 0.1 in a wavelength range from 200 nm to 380 nm; and
a light receiving unit that receives ultraviolet light that passes through the metal oxide film.

2. The light-receiving device according to claim 1, wherein
the metal oxide film has a minimum value of the extinction coefficient of not less than 0.4 in a wavelength range from 200 nm to 250 nm, and
the metal oxide film has an average value of the extinction coefficient of not less than 0.09 in a wavelength range from 250 nm to 380 nm.

3. The light-receiving device according to claim 1, wherein
a wavelength range of the ultraviolet light includes the wavelength range from 200 nm to 380 nm; and
the light receiving unit photoelectrically converts the ultraviolet light that passes through the metal oxide film.

4. The light-receiving device according to claim 1, wherein the metal oxide film includes one or more of tantalum oxide, niobium oxide, and tungsten oxide.

5. The light-receiving device according to claim 1, wherein the metal oxide film has a film thickness of not less than 1 nm and not more than 20 nm.

6. The light-receiving device according to claim 1, wherein
the metal oxide film includes tantalum oxide, and
the metal oxide film has a film thickness of not less than 1 nm and not more than 20 nm.

7. The light-receiving device according to claim 1, wherein standard free energy of formation of the metal oxide film is equal to or more than standard free energy of formation of silicon oxide.

8. A light-receiving device, comprising:
a lens that allows ultraviolet light to pass through;
a metal oxide film where light that passes through the lens enters; and
a light receiving unit that receives the light that passes through the lens and the metal oxide film, wherein
the metal oxide film has a maximum value of an extinction coefficient of not less than 0.1 in a wavelength range from 200 nm to 380 nm.

9. The light-receiving device according to claim 8, wherein the lens is configured using silicon oxide.

10. The light-receiving device according to claim 8, wherein
the metal oxide film has a minimum value of the extinction coefficient of not less than 0.4 in a wavelength range from 200 nm to 250 nm, and
the metal oxide film has an average value of the extinction coefficient of not less than 0.09 in a wavelength range from 250 nm to 380 nm.

11. The light-receiving device according to claim 8, wherein a wavelength range of the ultraviolet light includes the wavelength range from 200 nm to 380 nm.

12. The light-receiving device according to claim 8, wherein the metal oxide film includes one or more of tantalum oxide, niobium oxide, and tungsten oxide.

13. The light-receiving device according to claim 8, wherein the metal oxide film has a film thickness of not less than 1 nm and not more than 20 nm.

14. The light-receiving device according to claim 8, wherein
the metal oxide film includes tantalum oxide, and
the metal oxide film has a film thickness of not less than 1 nm and not more than 20 nm.

15. The light-receiving device according to claim 8, wherein standard free energy of formation of the metal oxide film is equal to or more than standard free energy of formation of silicon oxide.

16. The light-receiving device according to claim 1, comprising:
a fixed charge film provided between the metal oxide film and the light receiving unit.

17. The light-receiving device according to claim 16, wherein the fixed charge film includes aluminum oxide.

18. The light-receiving device according to claim 1, comprising:
a substrate including a plurality of the light receiving units, a plurality of holding sections, and a plurality of transfer units, the light receiving unit receiving light to generate a charge, the holding sections holding the charge, the transfer units transferring the charge generated by the light receiving units to the holding sections;
a wiring line layer provided on a side opposite to a side where the light enters; and
a controller that controls the plurality of the transfer units in a global shutter manner.

19. An electronic apparatus, comprising:
a light-receiving device including a metal oxide film and a light receiving unit that receives ultraviolet light that passes through the metal oxide film, wherein
the metal oxide film has a maximum value of an extinction coefficient of not less than 0.1 in a wavelength range from 200 nm to 380 nm.

20. An electronic apparatus, comprising
a light-receiving device including:
a lens that allows ultraviolet light to pass through;
a metal oxide film where light that passes through the lens enters; and
a light receiving unit that receives the light that passes through the lens and the metal oxide film, wherein
the metal oxide film has a maximum value of an extinction coefficient of not less than 0.1 in a wavelength range from 200 nm to 380 nm.
